(19) United States
(12) Patent Application Publication
(10) Pub. No.: US 2024/0341203 A1
(43) Pub. Date: Oct. 10, 2024

(54) SEMICONDUCTOR-SUPERCONDUCTOR HYBRID DEVICE INCLUDING AN ELECTRODE ARRAY

(71) Applicant: Microsoft Technology Licensing, LLC, Redmond, WA (US)

(72) Inventors: Charles Masamed MARCUS, Copenhagen (DK); Andreas Simon PÖSCHL, Copenhagen (DK); Alisa DANILENKO, Copenhagen (DK)

(73) Assignee: Microsoft Technology Licensing, LLC, Redmond, WA (US)

(21) Appl. No.: 18/579,259

(22) PCT Filed: Jul. 12, 2021
(86) PCT No.: PCT/EP2021/069284

§ 371 Date: Jan. 12, 2024

(51) Int. Cl. H10N 60/10; H10N 60/01

(52) U.S. Cl. CPC H10N 60/128; H10N 60/01; H10N 60/11

(57) ABSTRACT

A semiconductor-superconductor hybrid device comprises a semiconductor component which, when in use, comprises a channel in the form of a nanowire; a superconductor component capable of inducing superconductivity in the semiconductor component by proximity effect; and an array of finger gates. The finger gates are individually operable to apply respective electrostatic fields to respective segments of the channel. The array of finger gates allows for localized control over electrical potentials in the corresponding segments of the nanowire. Also provided are methods of fabricating and operating the semiconductor-superconductor hybrid device.

### BACKGROUND

Semiconductor nanowires proximitized by a superconductor are expected to host a topological phase of matter, provided the right conditions. This makes them a promising candidate as building blocks of a fault-tolerant quantum computer. A concrete realization is provided by a semiconductor nanowire based on a two-dimensional electron gas (“2DEG”) with proximity coupling to a conventional superconductor, which is typically grown as part of the epitaxial 2D wafer stack but can also be deposited after material growth during fabrication. This material platform has sizable spin-orbit coupling and large electron g-factor, key ingredients for the formation of a topological state. The 2D platform allows complex device geometries via top-down lithographic patterning involving etching and deposition.

The topological phase manifests itself in the form of a pair of Majorana zero modes (MZM) at the ends of the nanowire. Along the bulk of the wire, away from the ends, a gap in the single-electron spectrum is present. Experiments typically use tunneling spectroscopy at the ends of the nanowire to detect a zero-bias peak (ZBP) in tunneling conductance.

By forming a network of such nanowires and inducing the topological regime in parts of the network, it is possible to create a quantum bit which can be manipulated for the purpose of quantum computing. A quantum bit, also referred to as a qubit, is an element upon which a measurement with two possible outcomes can be performed, but which at any given time (when not being measured) can in fact be in a quantum superposition of the two states corresponding to the different outcomes.

To induce a topological phase, the device is cooled to a temperature where the superconductor (e.g. aluminum) exhibits superconducting behavior. The superconductor causes a proximity effect in the adjacent semiconductor, whereby a region of the semiconductor near the interface with the superconductor also exhibits superconducting properties, that is, a superconducting pairing gap is induced in the adjacent semiconductor. It is in this region of the semiconductor where the MZMs are formed when a magnetic field is applied to the device.

The role of the magnetic field is to lift the spin degeneracy in the semiconductor. Degeneracy in the context of a quantum system refers to the case where different quantum states have the same energy level. Lifting the degeneracy means causing such states to adopt different energy levels. Spin degeneracy refers to the case where different spin states have the same energy level. Spin degeneracy can be lifted by means of a magnetic field, causing an energy level spilt between the differently spin-polarized electrons. This is known as the Zeeman effect. The Zeeman energy, i.e. the magnitude of the energy level split, should be at least as large as the superconducting gap in order to close the trivial superconducting gap and reopen a topological gap in the system.

Inducing MZMs typically also requires adjusting the electrostatic potential of charge carriers in the nanowire by gating the nanowire with an electrostatic potential. The electrostatic potential is applied using a gate electrode. Applying an electrostatic potential manipulates the number of charge carriers in the conductance band or valence band of the semiconductor component.

There is a need to characterize the electronic properties of semiconductor-superconductor hybrid systems.

### SUMMARY

In one aspect, the present invention provides a semiconductor-superconductor hybrid device, comprising: a semiconductor component which, when in use, comprises a channel in the form of a nanowire; a superconductor component capable of inducing superconductivity in the semiconductor component by proximity effect; and an array of finger gates, the finger gates being individually operable to apply respective electrostatic fields to respective segments of the channel.

In another aspect, the present invention provides a method of operating the semiconductor-superconductor hybrid device, which method comprises: cooling the semiconductor-superconductive hybrid device to a temperature at which the superconductor component is superconductive; applying a magnetic field to at least the channel of the semiconductor-superconductor hybrid device; and applying voltages to the finger gates.

In a still further aspect, the present invention provides a method of fabricating the semiconductor-superconductor hybrid device, which method comprises: fabricating the semiconductor component; fabricating the superconductor component; and fabricating the array of finger gates.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Nor is the claimed subject matter limited to implementations that solve any or all of the disadvantages noted herein.

### BRIEF DESCRIPTION OF THE DRAWINGS

To assist understanding of embodiments of the present disclosure and to show how such embodiments may be put into effect, reference is made, by way of example only, to the accompanying drawings in which:

FIG. 1 is a plan view of an example semiconductor-superconductor hybrid device;

FIG. 2 is a schematic cross-section of a portion of the FIG. 1 device;

FIG. 3a is an optical micrograph of a chip including a device of the type shown in FIG. 1, the device being located at position A;

FIG. 3b is a scanning electron microscopy, SEM, image of position A of FIG. 3a;

FIG. 4 is a schematic cross-section illustrating an array of finger gates arranged on a semiconductor heterostructure;

FIG. 5 is a flowchart outlining a method of operating a semiconductor-superconductor hybrid device;

FIG. 6 is a plot showing an illustration of disorder of electrical potential along the length of a channel, compared with an ideal case; and

FIG. 7 is a flowchart outlining a method of fabricating a semiconductor-superconductor hybrid device.

### DETAILED DESCRIPTION OF EMBODIMENTS

As used herein, the verb ‘to comprise’ is used as shorthand for ‘to include or to consist of’. In other words, although the verb ‘to comprise’ is intended to be an open term, the replacement of this term with the closed term ‘to consist of’ is explicitly contemplated, particularly where used in connection with chemical compositions.

Directional terms such as “top”, “bottom”, “left”, “right”, “above”, “below”, “horizontal” and “vertical” are used herein for convenience of description and refer to the orientation shown in the relevant drawing. For the avoidance of any doubt, this terminology is not intended to limit the orientation of the device in an external frame of reference.

The term “channel” is used herein in the sense of a region of semiconductor through which a current can flow, rather than a physical trench in a material. A channel may, in particular, be in the form of a nanowire.

As used herein, the term “superconductor” refers to a material which becomes superconductive when cooled to a temperature below a critical temperature, T_{c}, of the material. The use of this term is not intended to limit the temperature of the device.

A “nanowire” is an elongate member having a nano-scale width, and a length-to-width ratio of at least 100, or at least 500, or at least 1000. A typical example of a nanowire has a width in the range 10 to 500 nm, optionally 50 to 100 nm or 75 to 125 nm. Lengths are typically of the order of micrometers, e.g., at least 1 μm, or at least 10 μm. A nanowire may be considered to be quasi one-dimensional.

The edges of a nanowire may be defined by material boundaries (for example, in the case of a selective-area-grown nanowire of semiconductor), or electrostatically (for example, by applying an electrostatic field to deplete charge carriers from a semiconductor to define the edge), or a combination of the two (for example, one edge may be a material boundary, with the other edge being defined electrostatically).

The term “coupling” in the context of the present disclosure refers to the hybridization of energy levels.

The term “magnetic field” encompasses ‘actual’ magnetic fields and ‘effective’ magnetic fields unless context clearly dictates otherwise. An ‘actual’ magnetic field, which may also be referred to as a ‘classical’ magnetic field, is a magnetic field of the type generated by an electromagnet or permanent magnet. An ‘effective’ magnetic field results from the spin-dependent scattering of electrons from a boundary between a conductive or super-conductive component and a ferromagnetic insulator component.

A “semiconductor-superconductor hybrid structure” comprises a semiconductor component and a superconductor component which may become coupled to one another under certain operating conditions. In particular, this term refers to a structure capable of showing topological behavior such as Majorana zero modes, or other excitations useful for quantum computing applications. The operating conditions generally comprise cooling the structure to a temperature below the T_{c} of the superconductor component, applying a magnetic field to the structure, and applying electrostatic gating to the structure. Generally, at least part of the semiconductor component is in intimate contact with the superconductor component, for example the superconductor component may be epitaxially grown on the semiconductor component. Certain device structures having one or more further components between the semiconductor component and superconductor component have however been proposed.

One technique which has been used to measure potentials is scanning tunneling microscopy, STM. STM comprises scanning a sample with a sharp metal tip to gain information about the density of states from the electrons that tunnel between the tip and the sample. Applying STM to a semiconductor-superconductor hybrid device is very difficult. It is hard to perform STM measurements under the conditions needed to induce a topological phase (low temperature, high magnetic field, etc.). Moreover, one would mostly measure the density of states of the parent superconductor.

For semiconductor-superconductor hybrid nanowires, tunneling conductance measurements may be performed. In a tunneling conductance measurement, ends of the nanowire which are not covered by superconductor material can be caused to operate like the tip of a scanning tunneling microscope. Electrons can tunnel from the semiconductor nanowire ends into the proximitized system and reveal information about the density of states at the ends of the nanowire. This type of measurement is however only applicable to ends of the device which are not coated with superconductor. It would be useful to allow measurements to be performed directly on portions of the device which are coated with superconductor.

Furthermore, disorder (i.e., random variations in electrical potential) in a nanowire may create unwanted topological boundaries along the length of the nanowire, and is harmful to the topological phase, and reduces its value for topological quantum computing. Moreover, zero bias peaks due to non-topological Andreev bound states (ABS) can also arise due to non-uniformity of the potential along the nanowire, particularly near the ends of the nanowire. The devices provided herein may be operable to compensate for disorder.

Here we disclose a device architecture that may allow in-situ fine-tuning of the potentials along a nanowire. For example, the device may allow potentials to be tuned to remove unwanted fluctuations due to disorder, or to allow the investigation of differently-shaped potentials. Device architectures described herein may provide a means of creating one or more tunneling contacts to the side of the wire at arbitrary locations. Tuning and measurement over length scales of the order of 100 nm may be achievable.

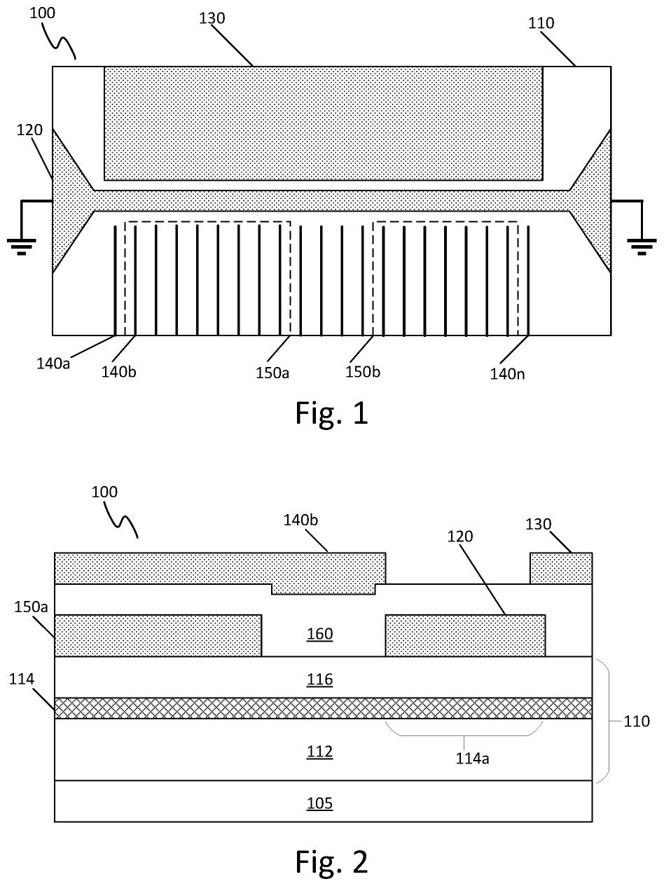

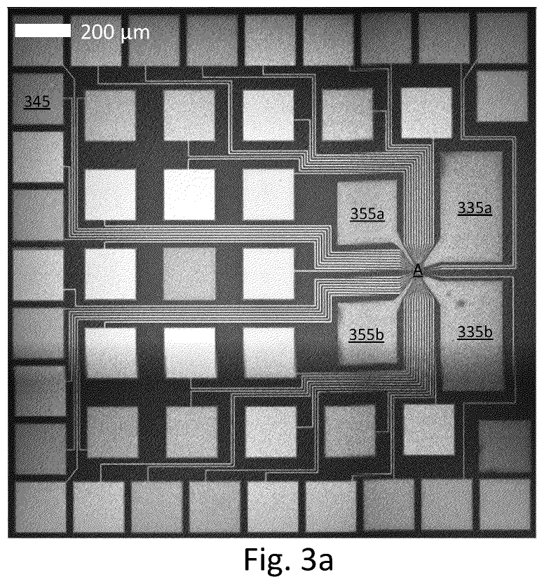

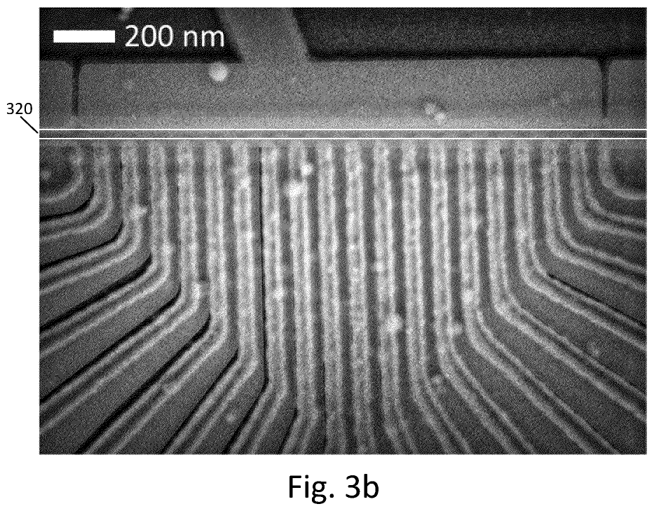

An example of a semiconductor-superconductor hybrid device 100 will now be described with reference to FIGS. 1 to 3. FIG. 1 is a schematic plan view of the device, and FIG. 2 is a schematic cross-section of a portion of the device. FIG. 3a is an optical micrograph of an example chip incorporating the device, and FIG. 3b is a scanning electron microscopy image of an example device.

The device 100 includes a semiconductor component 110 and a superconductor component 120 arranged on the semiconductor component. As illustrated in FIG. 2, the device is arranged on a substrate 105.

The substrate 105 provides a base on which the semiconductor component 110 is grown. The substrate 105 typically comprises a wafer, i.e., a piece of single crystalline material. One example wafer material is indium phosphide. Other examples of wafer materials include gallium arsenide, indium antimonide, indium arsenide, and silicon.

The substrate may further comprise additional structures arranged on or over the wafer. The substrate may include layers of two or more materials. In particular, the substrate may include a buffer layer. Good lattice matching between immediately adjacent layers of materials is desirable. In other words, adjacent layers desirably have lattice constants which are as similar as possible. To this end, the buffer layer may comprise a material which is selected to have a lattice constant which is between that of the crystalline substrate 105 and that of the following layer, which in this example is lower barrier 112 of semiconductor component 110.

The semiconductor component 110 in this example is a semiconductor heterostructure comprising a lower barrier 112 arranged epitaxially on the substrate 105; a quantum well 114 arranged epitaxially on the lower barrier 112; and an upper barrier 116 arranged epitaxially on the quantum well 114. The lower barrier 112, quantum well 114, and upper barrier 116 are each in the form of layers.

This structure is referred to as a heterostructure because the quantum well comprises a material which is different from the material(s) of the lower barrier and upper barrier. The materials of the lower barrier layer and the upper barrier layer may each be independently selected.

The configuration of the lower and upper barriers 112, 116 is not particularly limited, provided that these layers allow electrons to be trapped in the quantum well 114. The lower barrier 112 may comprise one or more layers of one or more different materials. The upper barrier 116 may comprise one or more layers of one or more different materials. Constructing a barrier from a plurality of layers may provide defect filtering, i.e. may reduce the effects of dislocations in the crystalline structure of the materials used.

Quantum well layer 114 may comprise a layer of semiconductor material which has a relatively small band gap compared to the materials of the lower and upper barriers 122, 126. Illustrative materials useful for forming quantum wells are described in, for example, Odoh and Njapba, “A Review of Semiconductor Quantum Well Devices”, Advances in Physics Theories and Applications, vol. 46, 2015, pp. 26-32; and S. Kasap, P. Capper (Eds.), “Springer Handbook of Electronic and Photonic Materials”, DOI 10.1007/978-3-319-48933-9_40.

In operation, charge is localized in the quantum well 114. In particular, the quantum well may host a 2-dimensional electron gas. The 2-dimensional electron gas may be further constrained to a region 114a through the use of gate electrodes, as will be discussed in more detail below. More particularly, the region 114a may be in the form of a nanowire. Useful excitations, such as Majorana zero modes, may be generated in such a nanowire. The region 114a may also be referred to as a channel.

The device further includes a superconductor component 120. In this example, the superconductor component comprises an elongate strip of superconductor material having a contact pad at each end. Example contact pads 335 are shown in FIG. 3a. The contact pads may each be connected to electrical ground. The elongate strip is arranged over the channel of the semiconductor component 110. In operation, energy level hybridization may occur between the superconductor material of the elongate strip, and the semiconductor material of channel 114a.

The nature of the superconductor is not particularly limited and may be selected as appropriate. The superconductor is typically an s-wave superconductor. Any of the various s-wave superconductors known the art may be used. Examples include aluminum, indium, tin, and lead, with aluminum being preferred in some contexts. In implementations where aluminum is used, the superconductor component may have a thickness in the range 3 to 20 nm.

As is illustrated in FIG. 2, the superconductor component is arranged on the upper barrier 116 of the semiconductor component 110, as opposed to being arranged directly on the channel 114a. The upper barrier layer 116 may serve to adjust the strength of the interaction between the superconductor component 120 and the channel. The concept of using a barrier layer to adjust the strength of interactions between a superconductor and a semiconductor is described in more detail in US 2021/0126181 A1.

The device 100 further comprises a boundary-depletion gate 130. In operation, the boundary-depletion gate 130 is used to apply an electrostatic field for defining one edge of the channel 114a, by depleting charge carriers from the quantum well 114 in the region underneath the boundary-depletion gate 130. The electrostatic field applied using the boundary-depletion gate 130 may also provide coarse adjustment of electrical potentials in the channel 114a.

The boundary-depletion gate has an edge which, in plan, is parallel to the edge of the elongate strip portion of superconductor component 120. As shown in FIG. 2, the boundary-depletion gate 130 may overlap the superconductor component 120, and may be separated from the superconductor component 120 by a dielectric 160. In such implementations, the superconductor component at least partially shields the channel 114a from the electrostatic field applied by the boundary-depletion gate.

The device 100 further includes an array of finger gates 140a, 140b . . . 140n. The array of gate electrodes 140 is arranged along an opposite side of superconductor component 120 to the boundary-depletion gate 130. Each finger gate of the array has an end which is adjacent, in plan, to the channel 114a.

A finger gate is a narrow gate electrode. Typically, a finger gate has a width of less than or equal to 150 nm, optionally less than 50 nm, or less than 25 nm. It may be desirable for each finger gate to be as narrow as possible. The minimum width is constrained only by the resolution of the method chosen to fabricate the finger gates.

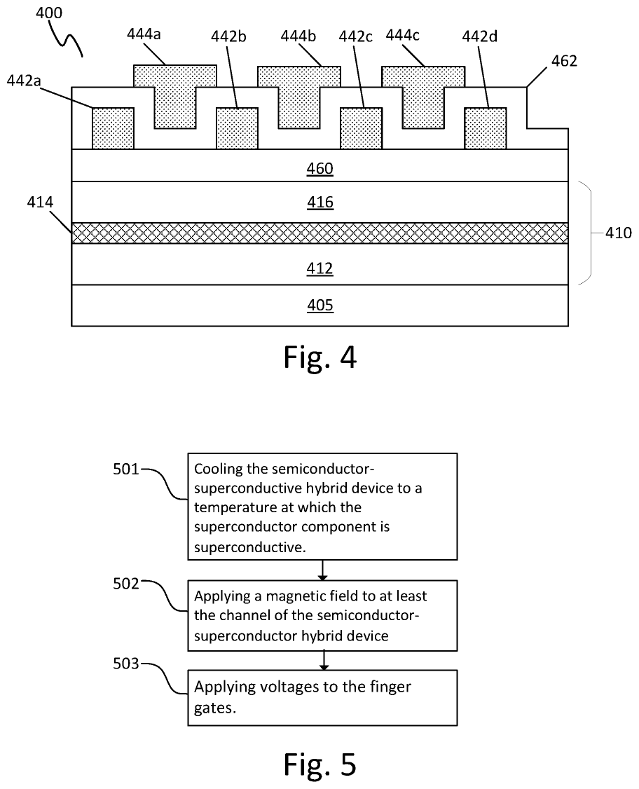

The spacing between laterally adjacent finger gates is preferably small, and may for example be less than 10 nm. As will be explained with reference to FIG. 4, laterally adjacent finger gates do not necessarily lie on the same plane. The finger gates are separated from one another by dielectric material, to prevent flow of current between finger gates.

The number of finger gates may be selected as desired, for example depending upon the length of the channel of the device. Typically, a device includes at least 10 finger gates. There is no particular upper limit on the number of finger gates in the array.

The device may be configured such that an individually selected voltage may be applied to each finger gate of the array 140. For example, each finger gate may be connected to a respective contact pad. FIG. 3a shows a plurality of contact pads 345 for an array of finger gates.

In operation, voltages are applied to finger gates of the array 140. The finger gates are operated to define an edge of the channel 114a. Each finger gate of the array applies an electrostatic field to a corresponding segment of the channel 114a. By applying individually selected voltages to individual ones of the finger gates 140, it is possible to control the electrical potential of individual segments of the channel. Fine control over potentials in the channel is useful for a variety of different purposes, as will be explained in more detail below with reference to methods of operating the device.

FIG. 3b is a scanning electron microscopy, SEM, image of part of region A of the chip shown in FIG. 3a. As may be seen, the device includes an array of closely-spaced finger gates. The image is annotated to show the location of the superconductor component 320. The channel of this device would be under the superconductor component.

The device 100 further includes leads 150a, 150b. The leads 150a, 150b are electrodes which are arranged under respective groups of finger gates 140. A group of finger gates which is a subset of the array 140 may be referred to as a subarray. The leads 150a, 150b are separated from the finger gates by dielectric 160. Each of the leads 150a, 150b may be operably linked to a respective amplifier circuit. The amplifier circuits may be arranged on the same substrate as the device. Alternatively, the leads may each be connected to a respective contact pad (e.g., contact pads 355a, 355b in FIG. 3a), which may in turn be connected to an amplifier circuit. An example of a suitable commercially available amplifier is the SP938c current-to-voltage convertor available from Basel Precision Instruments.

The edges of the leads 150a, 150b are adjacent to the channel 114a in plan. The distance between the edges of the leads 150a, 150b and the channel is selected to allow for tunneling of electrons between the leads and the channel 114a when an appropriate electrostatic field is applied to one of the finger gates of the sub-array. By causing a tunneling current to flow between the channel and one or both of the leads, various measurements may be performed on the channel. Example methods of measurement are discussed will be discussed below.

The leads may be fabricated from the same material as the superconductor component 120. By applying a magnetic field in a direction which is parallel to the elongate strip portion of the superconductor component, the lead may act as a normal conductor whilst the elongate strip of the superconductor component is superconductive.

Various modifications may be made to the example devices.

The inclusion of a boundary-depletion gate is optional. The edge of the channel may instead be provided by a material boundary. A material boundary may be formed by etching a semiconductor heterostructure to form a semiconductor component which is in the form of a mesa arranged on a substrate. Alternatively, the semiconductor component may be in the form of a selective-area-grown nanowire.

Although the illustrated example includes a single boundary-depletion gate, two or more boundary-depletion gates may be used. In such implementations, each boundary-depletion gate may be arranged opposite a subarray of the array of gate electrodes. In accordance with a further possibility, the boundary-depletion gate may be replaced by a second array of finger gates of the type described with reference to array of finger gates 140. The second array of finger gates may be associated with one or more leads of the type described with reference to leads 150a, 150b.

The example device includes two leads. Any number of leads may be present. The device may include a single lead, or three or more leads.

The inclusion of leads is optional in implementations where the capability to perform tunneling measurements is not required. In such implementations, the array of electrodes may be used to define a length of the channel and/or to compensate for disorder in the channel. Suitable gate voltages could be determined by trial and improvement, e.g., by incrementally adjusting individual gate voltages. The incremental adjustment could be controlled by a classical computer implementing a suitable optimization process.

An example configuration of an array of finger gates will now be described with reference to FIG. 4. FIG. 4 shows a schematic cross-section taken perpendicular to an array of finger gates in a device of the type shown in FIG. 1.

The illustrated structure 400 is arranged on a semiconductor component 410, over a substrate 405. The semiconductor component 410 is as described with reference to FIGS. 1 and 2, and comprises a quantum well 414 arranged between lower and upper barriers 412, 416.

Arranged on the semiconductor component 410 is a dielectric 460. Examples of materials useful as dielectrics include silicon oxides (SiOₓ), silicon nitrites (SiNₓ), aluminum oxides (AlOₓ), and hafnium oxides (HfOₓ). Two or more dielectric layers may be present. A dielectric 460 is useful for preventing a short-circuit if the finger gates or superconductor component would otherwise have an ohmic contact with the semiconductor component. The dielectric 460 may be useful for protecting the semiconductor component during fabrication of the finger gates, particularly in implementations where fabricating the finger gates includes an etching operation. The dielectric 460 may be omitted in implementations where there is a Schottky barrier between the semiconductor component and the superconductor component/finger gates.

A first layer of finger gates 442a, 442b, 442c, 440d is arranged on the dielectric 460. The finger gates of the first layer 442 are laterally spaced from one another.

A second dielectric 462 covers the first layer of finger gates 442. In this example, the second dielectric 460 also extends over the spaces between the finger gates of the first layer 442. The material used to form the second dielectric 462 is not particularly limited, and may for example comprise a material selected from silicon oxides (SiOₓ), silicon nitrites (SiNₓ), and hafnium oxides (HfOₓ).

The first layer of finger gates may be fabricated from a metal which has an insulating native oxide. Examples of such metals include aluminum, niobium, or tantalum, with aluminum being particularly preferred. This may allow the second dielectric 462 to be formed more conveniently, by oxidation of the metal. For example, the finger gates may be patterned and then exposed to oxygen in order to form the second dielectric 462. Alternatively, the finger gates may be patterned at the same time as fabricating the second dielectric, by using selective anodic oxidation to pattern the finger gates 442. In particular, the finger gates may comprise aluminum and the second dielectric may comprise aluminum oxide.

A second layer of finger gates 444a, 444b, 444c is arranged on the second dielectric 462, in the spaces between the finger gates of the first layer 442. Fabricating the finger gates in two stages may allow the lateral spacing between adjacent finger gates to be smaller than would otherwise be possible. The second dielectric may allow the first and second layers of finger gates to overlap in plan without creating short-circuits between finger gates.

Although in the illustrated example, second dielectric 362 extends into the spaces between the finger gates of the first set, in other implementations the second dielectric 362 may not be a unitary layer, and may cover just the finger gates 442 themselves. In particular, in implementations where the finger gates comprise aluminum, the dielectric may be the native oxide which forms on aluminum upon exposure to oxygen. The form of the dielectric 362 is not particularly limited, provided that adjacent finger gates are electrically isolated from one other.

A method of operating a semiconductor-superconductor hybrid device will now be described with reference to FIG. 5. FIG. 5 is a flow diagram outlining the method.

At block 501, the semiconductor-superconductor hybrid device is cooled to a temperature at which the superconductor component is superconductive. In other words, the device is cooled to a temperature which is below the critical temperature of the superconductor component. By way of illustration, a typical operating temperature for a device of the type provided herein might be less than or equal to 50 mK. The device is maintained at a temperature below the critical temperature throughout its operation.

Various cryogenic systems suitable for cooling a superconductor device to an operating temperature are known in the art. One illustrative example is a dilution refrigerator.

At block 502, a magnetic field is applied to at least the channel of the device.

The magnetic field may be an “actual” magnetic field, in other words a classical magnetic field, applied externally using an electromagnet or the like.

The magnetic field may be an “effective” magnetic field. The device may include a ferromagnetic insulator component which may provide a spin-dependent scattering of electrons from the interface between the superconductor and the ferromagnetic insulator. The spin-dependent scattering of electrons acts as an effective magnetic field. Examples of ferromagnetic insulators include EuS and EuO.

An effective magnetic field provided by a ferromagnetic insulator may be used in combination with an actual magnetic field provided by an electromagnet. In such implementations, the strength of the effective magnetic field can be controlled on average with an actual applied magnetic field.

Applying a magnetic field, either actual or effective (via spin dependent scattering), to the device may cause different spin states in the device to adopt different energy levels. This effect is referred to as “lifting spin degeneracy”. Lifting the spin degeneracy may close the trivial superconducting gap in the device and reopen a topological gap.

The magnetic field may include a component which is perpendicular to the spin-orbit field direction, e.g. parallel to the length of the elongate portion of the superconductor component arranged over channel 114a. The critical field of a components fabricated from a superconductor material may be anisotropic, in other words, may vary depending on the field direction of the magnetic field. In implementations where the device includes a lead, applying the magnetic field in a direction parallel to the length of the elongate portion of the superconductor component may cause the leads to act as normal conductors while the superconductor component remains superconductive. This may allow for normal-insulator-super (NIS) tunneling conductance between the channel and the lead, as opposed to super-insulator-super (SIS) tunneling conductance. By way of illustration, the critical field of the leads in the direction parallel to the channel may be of the order of about 200 mT.

A magnetic field is applied throughout operation of the device. By way of illustration, the magnetic field strength may be greater than or equal to 1 T.

In implementations where a boundary-depletion gate is used to define an edge of the channel, a gate voltage is applied to the boundary-depletion gate. The boundary depletion gate defines electrostatically the edge of the channel by depleting charge carriers from a region of the semiconductor component under the boundary-depletion gate. The boundary-depletion gate may also provide coarse electrostatic tuning are of electrical potentials in the channel.

At block 503, voltages are applied to the finger gates. This causes the finger gates to apply respective electrostatic fields to respective segments of the channel. The voltage which is applied to each finger gate may be individually selected. This may allow for control over electrostatic potentials in the channel. Various effects may be achieved by selecting the gate voltages.

The electrostatic potential in a nanowire varies randomly along its length. This is referred to as spatial disorder, or simply as disorder. There are various possible causes of disorder. Without wishing to be bound by theory, it is believed that charges trapped at interfaces between materials and impurities in materials may contribute to disorder. Disorder may make it difficult to induce an extended topological phase in a hybrid structure.

One use case for the array of finger gates is to compensate for disorder. By individually selecting gate voltages for each finger gate, local variations in the electrostatic potential in the corresponding segments of the nanowire may be counterbalanced. Each part of the nanowire may experience a different electrostatic field, with these different electrostatic fields acting to smooth out the disorder.

More generally, the array of finger gates may be used to control potentials at different sections along the nanowire. For example, it may be desirable to investigate the effects of different potentials on the behavior of the device. One may wish to study, for instance, the effect of a potential dip, or a potential bump, or a periodic (oscillatory in space with various wavelengths) variation of the potential, or, for example, a U-shaped variation in potential. The finger gates may be used to provide desired a tailored potential profile while at the same time compensating for disorder.

Another use case for the array finger gates is to allow control over the length of the channel. If an appropriate voltage is applied to a finger gate, that finger gate may deplete the corresponding segment of the nanowire. In other words, the corresponding segment of the nanowire is tuned to a trivial state. The depleted segment effectively becomes an end of the channel. The length of the channel is therefore selectable by operating selected ones of the finger gates to define the positions of ends of the channel.

Any combination of these three modes of operation, i.e., disorder compensation, potential tailoring, and control of the effective length is possible. For example, outer finger gates may be selected to define the length of the channel, and finger gates which are between the selected outer finger gates may be operated to control electrostatic potentials in the channel to compensate for disorder and/or to provide a tailored potential profile. The selected outer finger gates may be single finger gates or groups of finger gates.

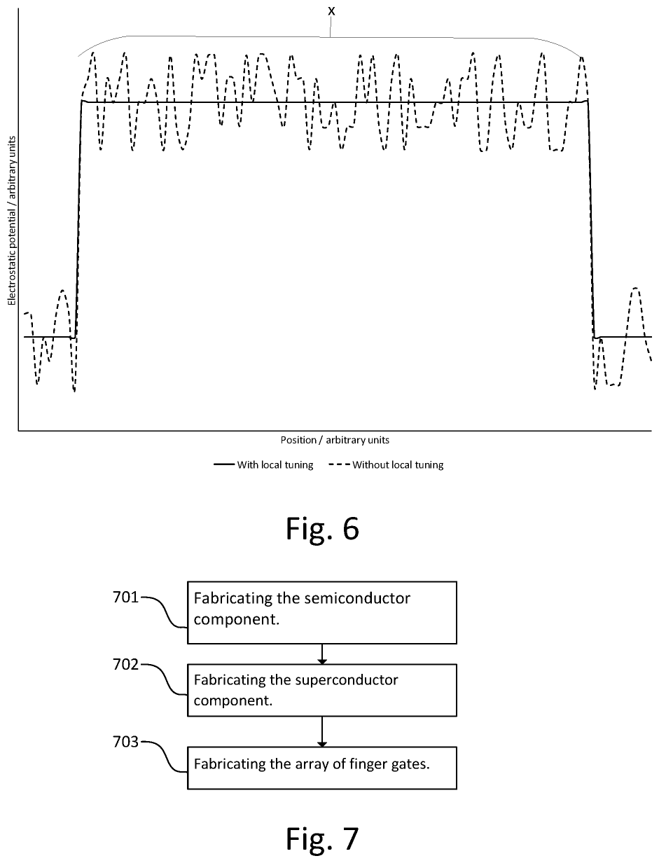

These two use cases are illustrated in FIG. 6. FIG. 6 is a simulated plot illustrating electrostatic potentials along the length of a nanowire.

The solid trace in FIG. 6 shows an idealized case, where a constant electrostatic potential is induced in a channel of length x in a nanowire.

The dashed trace in FIG. 6 shows an illustration of random variations in electrostatic potential along the length of the nanowire, in comparison with an idealized case.

The array of finger gates is operable to control the length x of the channel, by selecting finger gates or groups of finger gates at either end of the nanowire, and causing the selected finger gates to deplete corresponding regions of the nanowire. The finger gates which are arranged along the length x of the channel are operable to compensate for the disorder in the electrostatic potential, bringing the actual potential closer to the idealized case.

In this example, a single channel is defined on the nanowire. It is also contemplated that the array of finger gates may be operated to define two or more channels along a single nanowire. In other words, finger gates may be operable to define junctions between a plurality of channels arranged in series. This may be useful for constructing a qubit device comprising a plurality of operably linked channels.

In implementations where the semiconductor-superconductor hybrid device includes at least one lead, the finger gates may be operable to allow various measurements of the electronic properties of the channel to be made.

These measurements rely on tunneling of electrons between the channel and the lead. The array of finger gates allows control over where the tunneling occurs, allowing electronic properties at different points along the nanowire to be characterized. This may provide a substitute for scanning tunneling microscopy, which cannot practically be applied to semiconductor-superconductor hybrid devices due to the conditions under which such devices operate and the challenges posed by the presence of a superconductor layer over the channel.

To cause tunneling of electrons between the channel and a lead, a finger gate which is arranged over a lead is selected. A voltage which does not fully deplete the semiconductor material which is between the channel and the lead is applied to the selected finger gate. This voltage is typically zero or a positive voltage compared to the potential of the channel. This may allow for tunneling conductance between the channel and the lead at the location of the selected finger gate, with the semiconductor acting as a tunable tunnel barrier. A finger gate which is operated in this way may be referred to herein as being in “spectroscopy mode”.

At the same time, other finger gates in the array may be operated to define ends of the channel, to compensate for disorder, and/or to tailor potentials in the channel as previously described. Particularly, other finger gates may be operated to counteract or modify any alteration of the electrostatic potential in the channel caused by operating the selected finger gate in spectroscopy mode.

The tunneling current through the lead is measured. This may include the use of an amplifier circuit connected to the lead to amplify the tunneling current. Information about the electronic properties of the channel at the location of the selected finger gate may be determined based on the measured tunneling current. For example, if a Majorana zero mode is present at the location of the selected finger gate, or in other words the selected finger gate corresponds to an end of a topological region, a zero bias peak may be observed. Conversely, if the finger gate that is in spectroscopy mode is located in the center of the topological region, a gap around zero bias may be observed in tunneling conductance.

Voltage biases may optionally be applied to the lead(s), and tunneling current may be measured as a function of the voltage bias.

The properties of the channel may be scanned, by iteratively selecting one or more different finger gates of the array to operate in spectroscopy mode and measuring the tunneling current for the selected finger gate(s). One finger gate, or any combination of finger gates, may be operated in spectroscopy mode at a time, depending on the measurement being performed.

When a new gate is selected to operate in spectroscopy mode, voltages applied to other gates of the array may be modified to counteract any alteration of electrostatic potentials in the channel resulting from operating that selected gate in spectroscopy mode, or to modify the electrostatic potentials in the channel. In other words, each iteration may include modifying voltages applied to one or more further finger gates in addition to modifying the voltage applied to selected finger gate.

The measured tunneling current may be a local tunneling current. To measure a local tunneling current, one finger gate of the array is operated in spectroscopy mode. The method may include determining a local conductance based on the local tunneling current.

The measured tunneling current may be a non-local tunneling current. Non-local tunneling currents may be measured when the device includes two leads, and at least one finger gate associated with each lead is operated in spectroscopy mode. The tunneling currents may provide a measure of current through the channel, since current may flow from one lead to another through the channel. A non-local conductance may be determined based on a non-local tunneling current. The size of a topological gap of the channel may be determined based on the non-local conductance.

More generally, any number of finger gates arranged over any number of leads may be operated in spectroscopy mode, allowing measurements through any number of terminals.

A voltage bias may be applied to the leads during the measurement. It may be desirable to measure tunneling conductance as a function of voltage bias on the leads.

The spatial resolution of the measurement depends upon the spacing of the finger gates. A spatial resolution of about 100 nm may be achievable.

A method of fabricating a semiconductor-superconductor hybrid device of the type described herein will now be explained with reference to FIG. 7. FIG. 7 is a flow diagram outlining the method.

At block 701, the semiconductor component is fabricated. Fabricating the semiconductor component typically comprises growing one or more layers of one or more semiconductor materials over a substrate. Examples of useful techniques for growing semiconductor components include molecular beam epitaxy (MBE), metal-organic vapor phase epitaxy (MOVPE), and the like.

Fabricating the semiconductor component may optionally further comprise etching the layers of semiconductor material selectively to form a semiconductor component having a desired shape. For example, the layers may be etched to form a mesa. The etch may be performed before or after fabricating the superconductor component. An example etchant composition useful for etching III-V semiconductor materials comprises an aqueous solution of citric acid, phosphoric acid, and hydrogen peroxide.

At block 702, the superconductor component is fabricated.

Fabricating the superconductor component may comprise globally depositing a layer of superconductor material over the semiconductor component, and then patterning the layer of superconductor material to form the superconductor component. As used herein, “global deposition” means covering an entire surface in deposited material. The patterning may comprise a lift-off process, or a selective etch controlled by a mask. Suitable etchants for superconductor materials are commercially available. One example etchant which is suitable for etching aluminum is Transene D, which is an aqueous solution of phosphoric acid, sodium-n-nitrobenzene sulfonate, and acetic acid.

Alternatively, the superconductor component may be fabricated by selective deposition of superconductor material. For example, the superconductor component may be fabricated by directional deposition controlled by shadow walls. A shadow wall is a structure arranged on a substrate which blocks a beam of material, thereby defining a shadow region in which the material is not deposited. One example method which makes use of shadow walls is described in US 2020/0243742 A1.

In implementations where the device includes one or more leads, the one or more leads may be fabricated from the superconductor material at the same time as the superconductor component is fabricated. Alternatively, the one or more leads may be fabricated in a separate step. When the one or more leads are fabricated separately from the superconductor component, the one or more leads may comprise a different material to that of the superconductor component.

At block 703, the array of finger gates is fabricated. Any boundary-depletion gates or further gate electrodes may be fabricated at the same time as the array of finger gates.

In implementations where the semiconductor-superconductor hybrid device includes one or more leads, fabricating the array of finger gates may comprise depositing a layer of dielectric material over the one or more leads and the superconductor component, and then forming the array of finger gates on the layer of dielectric material. The layer of dielectric material may be grown by atomic layer deposition.

Forming the array of finger gates may comprise a global deposition of electrode material, and then patterning the electrode material to form the array of finger gates.

The array of finger gates may be fabricated in stages. A first set of spaced-apart finger gates may be fabricated on the layer of dielectric material. A dielectric may then be formed over the first set of finger gates. Forming the dielectric may comprise depositing a layer of dielectric, for example by atomic layer deposition. Alternatively, in implementations where the finger gates are formed of a metal which has an insulating native oxide such as aluminum, forming the dielectric may comprise oxidizing the surface of the finger gates of the first set. After forming the dielectric, a second set of finger gates may be formed in the spaces the finger gates of the first set. This may allow for the finger gates to be packed together more closely.

It will be appreciated that the above embodiments have been described by way of example only.

More generally, according to one aspect disclosed herein, there is provided a semiconductor-superconductor hybrid device, comprising: a semiconductor component which, when in use, comprises a channel in the form of a nanowire; a superconductor component capable of inducing superconductivity in the semiconductor component by proximity effect; and an array of finger gates, the finger gates being individually operable to apply respective electrostatic fields to respective segments of the channel. The array of finger gates allows for localized control over electrical potentials in the corresponding segments of the nanowire.

The channel may, for example, have a width in the range 10 to 125 nm, and a length of at least 1 μm. The superconductor component may comprise an elongate strip, arranged over the channel.

The semiconductor component may be a heterostructure comprising a quantum well arranged between upper and lower barriers. The use of an array of finger gates has, in particular, been investigated for devices based on quantum wells. Other semiconductor components, such as selective-area-grown components, may alternatively be used.

The device further may comprise a boundary-depletion gate operable to define electrostatically a first edge of the channel. The array of finger gates may be operable to define electrostatically a second edge of the channel, opposite the first edge.

The semiconductor-superconductor hybrid device may further comprise: a first lead, the lead being arranged under a first sub-array of the array of finger gates; and a dielectric arranged between the lead and the array of finger gates. The first lead may have an edge which is spaced from the channel by a distance selected to allow for electron tunneling between the channel and the lead. By way of illustration, the distance may be in the range to 200 nm. In such implementations, measurement of tunneling currents between the lead and the channel when a finger gate is tuned to an appropriate regime is made possible. This may allow for investigation of the electronic properties of the channel.

The lead may be operably linked to an amplifier circuit. The amplifier circuit may be a current-to-voltage amplifier. Amplifier circuits are useful for amplifying the tunneling current, to allow for easier detection of the tunneling current.

The semiconductor-superconductor hybrid device may further comprise a second lead. The second lead may be arranged under a second sub-array of the array of finger gates, separate from the first sub-array. The dielectric may be further arranged between the second lead and the array of finger gates. The second lead may have an edge which is spaced from the channel by a distance selected to allow for electron tunneling between the channel and the second lead.

Like the first lead, the second lead may be operably linked to an amplifier circuit. The amplifier circuit may be a current-to-voltage amplifier.

The inclusion of at least two leads may allow a wider range of electronic properties of the channel to be measured. For example, measurements of non-local conductance may be made possible.

The devices provided herein may comprise any number of leads.

The array of finger gates may comprise a lower layer of finger gates and an upper layer of finger gates. The device may further comprise a dielectric covering the lower layer of finger gates. The upper layer of finger gates may be arranged on top of the dielectric and may be laterally offset from the lower layer of finger gates. The dielectric may define recesses corresponding to spaces between the finger gates of the lower layer. The finger gates of the upper layer may be arranged at least partially in the recesses. By fabricating the array of finger gates in two stages, a higher density of finger gates may be achieved. For example, the first set of finger gates may provide a template for guiding the fabrication of the second set of finger gates.

The finger gates of the lower layer may comprise a metal which has an insulating native oxide. The dielectric layer may comprise the native oxide of the metal. This may allow the dielectric between the finger gates to be formed more conveniently. For example, the metal may be aluminum, which can form a native oxide when simply exposed to oxygen.

Each of the finger gates may have a width of less than or equal to 150 nm, and optionally less than or equal to 25 nm. The spacing between adjacent finger gates may be less than or equal to 25 nm. By providing narrow, closely spaced finger gates, higher resolution control over and/or measurement of the electronic properties of the channel may be made possible.

The number of finger gates may be selected as appropriate depending upon the length of the channel. The array of finger gates may comprise at least 10 finger gates, optionally at least 40 gate electrodes. Providing a large number of finger gates may allow for greater control over the electronic properties of the nanowire.

The superconductor component may comprise an elongate strip of superconductor. The elongate strip may be arranged over the channel. The elongate strip may have a width of less than or equal to 125 nm. The superconductor component may have two ends. Each of the two ends may be electrically grounded.

Another aspect provides a method of operating the semiconductor-superconductor hybrid device. The method comprises: cooling the semiconductor-superconductive hybrid device to a temperature at which the superconductor component is superconductive; applying a magnetic field to at least the channel of the semiconductor-superconductor hybrid device; and applying voltages to the finger gates.

Applying the voltages to the finger gates may comprise applying individually selected voltages to respective ones of the finger gates. For example, applying the voltages to the finger gates may comprise operating at least one finger gate to compensate for local disorder in respective segment of the channel. By “local disorder” is meant a random deviation in the electrostatic potential of the nanowire from a target electrostatic potential. Local disorder may arise from, e.g., trapped charges, impurities in materials, and other sources. Compensating for disorder in the channel may allow an extended topological phase to be induced in the device.

Alternatively or additionally, applying individually-selected voltages to respective ones of the finger gates may comprise inducing a predetermined potential profile in the channel.

The method may further comprise selecting a finger gate to act as a first end finger gate. Applying the voltages may comprise operating the first end finger gate to deplete charge carriers from a respective segment of the channel, thereby defining a first end of an active portion of the channel.

The method may further comprise selecting a finger gate to act as a second end finger gate; and applying the voltages comprises operating the second finger gate to deplete charge carriers from a respective segment of the channel, thereby defining a second end of the active portion of channel. The array of finger gates may be operated to control the length of the active portion of the channel, by selectively depleting charge carriers from an end of the channel. The method may further comprise changing the length of the active portion of the channel, e.g. by selecting a new combination of finger gates to act as first and second end finger gates.

The method may include compensating for disorder and/or tailoring potentials in the channel in addition to controlling the length of the channel. For example, the first end finger gate and the second end finger gate may have further finger gates therebetween; and applying the voltages may comprise operating the further finger gates to compensate for local disorder in respective segments of the channel.

Finger gates which are not aligned with the active portion of the channel, i.e. are beyond the first end finger gate and the second end finger gate, may be operated to deplete charge carriers from the respective segments of the channel. A group of adjacent finger gates may be operated to define the first end of the channel. A group of adjacent finger gates may be operated to define a second end of the channel.

The device may further comprise a first lead, the lead being arranged under first a sub-array of the array of finger gates; and a dielectric arranged between the lead and the array of finger gates. The first lead may have an edge which is spaced from the channel by a distance selected to allow for electron tunneling between the channel and the lead. In such implementations, the method may further comprise: selecting one finger gate of the first sub-array; and measuring a tunneling current by applying a voltage to the selected finger gate which is selected to cause tunneling of electrons between the first lead and the segment of the channel corresponding to the selected finger gate; and measuring an electrical current through the first lead. Measurement of the tunneling current may allow for the determination of electronic properties of the channel. For example, the detection of a zero bias peak may be indicative of the presence of a Majorana zero mode at the segment of the channel corresponding to the selected finger gate.

The method may further comprise applying a bias voltage to the first lead.

The method may comprise measuring tunneling current using the selected finger gate, and at the same time operating at least one other finger gate to compensate for local disorder in the channel. The method may further comprise, at the same time, controlling the length of channel using at least one other finger gate.

The method may further comprise selecting a different finger gate of the first sub-array, and measuring the tunneling current. The electronic properties along the length of the channel may be characterized by measuring tunneling currents at a plurality of different segments of the nanowire. Measurements of tunneling currents may provide a measure of electrical potentials in the channel, and as such may be useful for characterizing the properties of the channel.

The device may further comprise a second lead, the second lead being arranged under a second sub-array of the array of finger gates, separate from the first sub-array; and the dielectric may further be arranged between the second lead and the array of finger gates. The second lead may have an edge which is spaced from the channel by a distance selected to allow for electron tunneling between the channel and the second lead. The method may further comprise selecting one finger gate of the second sub-array; and measuring a tunneling current by applying a voltage to the selected finger gate which is selected to cause tunneling of electrons between the first lead and the segment of the channel corresponding to the selected finger gate; and measuring an electrical current through the second lead. By measuring tunneling current through two or more leads simultaneously, it may be made possible to determine a non-local conductance through the channel based on the tunneling current. The method may further comprise applying bias voltages, e.g. source and drain biases, to the first and second leads.

The method may further comprise selecting a different combination of finger gates and measuring the tunneling current. By iterating over combinations of finger gates, electronic properties through different parts of the channel may be measured.

The method may further comprise determining, based on the measured electrical currents, a non-local conductance through the channel.

It will be appreciated that the device used in the practice of the method aspect may have any of the features described with reference to the device aspect.

A still further aspect provides a method of fabricating a semiconductor-superconductor hybrid device of the type described herein. The method comprises: fabricating the semiconductor component; fabricating the superconductor component; and fabricating the array of finger gates.

Fabricating the semiconductor component may comprise: forming a semiconductor heterostructure in the form of a stack on a substrate, and selectively removing the semiconductor heterostructure by etching to form the semiconductor component in the form of a mesa.

Additional metal components such bonding pads and transmission lines may then be fabricated. Subsequently the array of finger gates may be fabricated. Fabricating the additional metal components separately from the gates of the active portion of the device may be useful, because the additional metal components may be thicker that the gates and may use lower resolution fabrication processes.

Fabricating the array of finger gates may comprise: forming a lower layer of finger gates, the lower layer of finger gates comprising a plurality of finger gates having spaces therebetween; forming a dielectric over the lower layer of finger gates; and forming an upper layer of finger gates on the dielectric, the finger gates of the upper layer being arranged over the spaces between the finger gates of the lower layer. By fabricating the array of finger gates in two stages in this way, a higher density of finger gates may be obtained. For example, constraints which would otherwise be imposed by the limited resolution of techniques such as electron beam lithography may be lifted.

The lower layer of finger gates may be formed from a metal which has an insulating native oxide; and the dielectric comprises the native oxide of the metal. This may allow for convenient formation of the dielectric, without the need for a step of depositing a layer of dielectric over the lower layer of finger gates.

Other variants or use cases of the disclosed techniques may become apparent to the person skilled in the art once given the disclosure herein. The scope of the disclosure is not limited by the described embodiments but only by the accompanying claims.

1. A semiconductor-superconductor hybrid device, comprising:
a semiconductor component which, when in use, comprises a channel in the form of a nanowire;
a superconductor component capable of inducing superconductivity in the semiconductor component by proximity effect; and
an array of finger gates, the finger gates being individually operable to apply respective electrostatic fields to respective segments of the channel.

2. The semiconductor-superconductor hybrid device according to claim 1, further comprising:
a first lead, the first lead being arranged under a first sub-array of the array of finger gates; and
a dielectric arranged between the first lead and the array of finger gates;
wherein the first lead has an edge which is spaced from the channel by a distance selected to allow for electron tunneling between the channel and the first lead.

3. The semiconductor-superconductor hybrid device according to claim 2, further comprising a second lead,
wherein the second lead is arranged under a second sub-array of the array of finger gates, separate from the first sub-array;
wherein the dielectric is further arranged between the second lead and the array of finger gates; and
wherein the second lead has an edge which is spaced from the channel by a distance selected to allow for electron tunneling between the channel and the second lead.

4. The semiconductor-superconductor hybrid device according to claim 1, wherein the semiconductor component is a heterostructure comprising a quantum well arranged between upper and lower barriers;
wherein the semiconductor-superconductor hybrid device further comprises a boundary depletion gate operable to define electrostatically a first edge of the channel; and
wherein the array of finger gates is operable to define electrostatically a second edge of the channel, opposite the first edge.

5. The semiconductor-superconductor device according to claim 1, wherein the array of finger gates comprises a lower layer of finger gates and an upper layer of finger gates; and
wherein the device further comprises a dielectric layer covering the lower layer of finger gates, wherein the upper layer of finger gates is arranged on top of the dielectric layer and is laterally offset from the lower layer of finger gates.

6. The semiconductor-superconductor hybrid device according to claim 5, wherein the dielectric layer defines recesses corresponding to spaces between the finger gates of the lower layer; and
wherein the finger gates of the upper layer are arranged at least partially in the recesses.

7. (canceled)

8. The semiconductor-superconductor hybrid device according to claim 1, wherein the superconductor component comprises an elongate strip of superconductor, wherein the elongate strip is arranged over the channel, and wherein the elongate strip has a width of less than or equal to 125 nm.

9. A method of operating a semiconductor-superconductor hybrid device, the semiconductor-superconductor hybrid device comprising:
a semiconductor component which, when in use, comprises a channel in the form of a nanowire;
a superconductor component capable of inducing superconductivity in the semiconductor component by proximity effect; and
an array of finger gates, the finger gates being individually operable to apply respective electrostatic fields to respective segments of the channel;
wherein the method comprises:
cooling the semiconductor-superconductive hybrid device to a temperature at which the superconductor component is superconductive;
applying a magnetic field to at least the channel of the semiconductor-superconductor hybrid device; and
applying voltages to the finger gates.

10. The method according to claim 9, wherein applying the voltages to the finger gates comprises applying individually selected voltages to respective ones of the finger gates.

11. The method according to claim 10, further comprising:
selecting a finger gate to act as a first end finger gate;
wherein applying the voltages comprises operating the first end finger gate to deplete charge carriers from a respective segment of the channel, thereby defining a first end of an active region of the channel.

12. The method according to claim 11, further comprising changing the length of the active region of the channel.

13. The method according to claim 9, wherein the device further comprises:
a first lead, the first lead being arranged under a first sub-array of the array of finger gates; and
a dielectric arranged between the lead and the array of finger gates;
wherein the first lead has an edge which is spaced from the channel by a distance selected to allow for electron tunneling between the channel and the first lead; and
wherein the method further comprises:
selecting one finger gate of the first sub-array; and
measuring a tunneling current by:
applying a voltage to the selected finger gate which is selected to cause tunneling of electrons between the first lead and the segment of the channel corresponding to the selected finger gate; and
measuring an electrical current through the first lead.

14. The method according to claim 13, wherein the device further comprises:
a second lead,
wherein the second lead is arranged under a second sub-array of the array of finger gates, separate from the first sub-array;
wherein the dielectric is further arranged between the second lead and the array of finger gates;
wherein the second lead has an edge which is spaced from the channel by a distance selected to allow for electron tunneling between the channel and the second lead;
wherein the method further comprises:
selecting one finger gate of the second sub-array; and
measuring a tunneling current by:
applying a voltage to the selected finger gate which is selected to cause tunneling of electrons between the first lead and the segment of the channel corresponding to the selected finger gate;
applying respective voltage biases to the first lead and the second lead; and
measuring an electrical current through the second lead.

15. A method of fabricating a semiconductor-superconductor hybrid device, the semiconductor-superconductor hybrid device comprising:
a semiconductor component which, when in use, comprises a channel in the form of a nanowire;
a superconductor component capable of inducing superconductivity in the semiconductor component by proximity effect; and
an array of finger gates, the finger gates being individually operable to apply respective electrostatic fields to respective segments of the channel;
wherein the method comprises:
fabricating the semiconductor component;
fabricating the superconductor component; and
fabricating the array of finger gates.

16. The method according to claim 15, wherein fabricating the array of finger gates comprises:
forming a lower layer of finger gates, the lower layer of finger gates comprising a plurality of finger gates having spaces therebetween;
forming a dielectric over the lower layer of finger gates; and
forming an upper layer of finger gates on the dielectric, the finger gates of the upper layer being arranged over the spaces between the finger gates of the lower layer.

17. The method according to claim 16, wherein the lower layer of finger gates is formed from a metal which has an insulating native oxide and the dielectric comprises the native oxide of the metal.

18. The semiconductor-superconductor hybrid device according to claim 1, further comprising a further array of finger gates arranged on an opposite side of the channel to the array of finger gates, the arrays of finger gates being operable to define electrostatically opposed edges of the channel.

19. The method according to claim 10, wherein applying the voltages to the finger gates comprises operating at least one finger gate to compensate for local disorder in respective segment of the channel.

20. The method according to claim 11, further comprising:
selecting a finger gate to act as a second end finger gate;
wherein applying the voltages comprises operating the second finger gate to deplete charge carriers from a respective segment of the channel, thereby defining a second end of the active region of the channel.

21. The method according to claim 20, wherein the first end finger gate and the end second finger gate have further finger gates therebetween and applying the voltages comprises operating the further finger gates to compensate for local disorder in respective segments of the active region of the channel.
